(19) United States
(12) Patent Application Publication
(10) Pub. No.: US 2024/0423003 A1
(43) Pub. Date: Dec. 19, 2024

(54) DETECTION DEVICE

(71) Applicant: Japan Display Inc., Tokyo (JP)

(72) Inventor: Gen KOIDE, Tokyo (JP)

(21) Appl. No.: 18/820,946

(22) Filed: Aug. 30, 2024

Related U.S. Application Data
(63) Continuation of application No. PCT/JP2023/006912, filed on Feb. 27, 2023.

(30) Foreign Application Priority Data
Mar. 8, 2022 (JP) 2022-035012

(51) Int. Cl. H10K 39/32; H10K 39/38

(52) U.S. Cl. CPC H10K 39/32; H10K 39/38

(57) ABSTRACT

According to an aspect, a detection device includes: a substrate; a plurality of photodiodes that are arranged on the substrate and each include a lower electrode, a lower buffer layer, an active layer, an upper buffer layer, and an upper electrode that are stacked on the substrate in the order as listed; a plurality of signal lines electrically coupled to the respective lower electrodes of the photodiodes; a detection circuit electrically coupled to the photodiodes through the signal lines; and a shield layer disposed between the signal lines in plan view.

### CROSS-REFERENCE TO RELATED APPLICATION

This application claims the benefit of priority from Japanese Patent Application No. 2022-035012 filed on Mar. 8, 2022 and International Patent Application No. PCT/JP2023/006912 filed on Feb. 27, 2023, the entire contents of which are incorporated herein by reference.

### BACKGROUND

### 1. Technical Field

What is disclosed herein relates to a detection device.

### 2. Description of the Related Art

Optical sensors capable of detecting fingerprint patterns and vein patterns are known (refer to, for example, Japanese Patent Application Laid-open Publication No. 2009-032005). Among such optical sensors, sensors are known each including a plurality of photodiodes in which an organic semiconductor material is used as an active layer. The organic semiconductor material is disposed between lower and upper electrodes, and signal lines are electrically coupled to the lower electrodes of the photodiodes to output detection signals to a detection circuit.

If parasitic capacitance generated between the signal lines or between the signal line and the lower electrode that are adjacent to each other increases, variations in potential (also called crosstalk) may occur between the signal lines or between the signal line and the lower electrode that are adjacent to each other. As a result, errors may occur in the detection signals output from the photodiodes to the detection circuit.

For the foregoing reasons, there is a need for a detection device capable of improving accuracy of detection.

### SUMMARY

According to an aspect, a detection device includes: a substrate; a plurality of photodiodes that are arranged on the substrate and each include a lower electrode, a lower buffer layer, an active layer, an upper buffer layer, and an upper electrode that are stacked on the substrate in the order as listed; a plurality of signal lines electrically coupled to the respective lower electrodes of the photodiodes; a detection circuit electrically coupled to the photodiodes through the signal lines; and a shield layer disposed between the signal lines in plan view.

According to an aspect, a detection device includes: a substrate; a plurality of photodiodes that are arranged on the substrate and each include a lower electrode, a lower buffer layer, an active layer, an upper buffer layer, and an upper electrode that are stacked on the substrate in the order as listed; a plurality of signal lines electrically coupled to the respective lower electrodes of the photodiodes; a detection circuit electrically coupled to the photodiodes through the signal lines; and a shield layer disposed between a plurality of the lower electrodes in plan view.

According to an aspect, a detection device includes: a substrate; a plurality of photodiodes that are arranged on the substrate and each include a lower electrode, a lower buffer layer, an active layer, an upper buffer layer, and an upper electrode that are stacked on the substrate in the order as listed; a plurality of signal lines electrically coupled to the lower electrodes of the photodiodes; a detection circuit electrically coupled to the photodiodes through the signal lines; and a shield layer disposed between the signal lines and the lower electrodes in plan view.

### BRIEF DESCRIPTION OF THE DRAWINGS

FIG. 1 is a plan view illustrating a detection device according to a first embodiment;

FIG. 2 is a sectional view along II-II′ of FIG. 1;

FIG. 3 is a sectional view along III-III′ of FIG. 1;

FIG. 4 is a plan view illustrating a detection device according to a first modification;

FIG. 5 is a sectional view along V-V′ of FIG. 4;

FIG. 6 is a sectional view along VI-VI′ of FIG. 4;

FIG. 7 is a sectional view schematically illustrating signal lines and shield layers of a detection device according to a second modification;

FIG. 8 is a sectional view schematically illustrating the signal lines and a shield layer of a detection device according to a third modification;

FIG. 9 is a sectional view schematically illustrating the signal lines and shield layers of a detection device according to a fourth modification;

FIG. 10 is a side view illustrating an exemplary use of the detection device according to the first embodiment for measuring biometric information;

FIG. 11 is a plan view illustrating a detection device according to a second embodiment;

FIG. 12 is a sectional view along XII-XII′ of FIG. 11;

FIG. 13 is a plan view illustrating a detection device according to a third embodiment;

FIG. 14 is a circuit diagram illustrating the detection device according to the third embodiment;

FIG. 15 is a plan view illustrating, in an enlarged manner, a plurality of photodiodes and a shield layer in FIG. 13;

FIG. 16 is a sectional view along XVI-XVI′ of FIG. 15;

FIG. 17 is a plan view illustrating, in an enlarged manner, the photodiodes and shield layers of a detection device according to a fifth modification;

FIG. 18 is a plan view illustrating, in an enlarged manner, the photodiodes and shield layers of a detection device according to a sixth modification;

FIG. 19 is a sectional view along XIX-XIX′ of FIG. 18;

FIG. 20 is a plan view illustrating a detection device according to a seventh modification; and

FIG. 21 is a sectional view along XXI-XXI′ of FIG. 20.

### DETAILED DESCRIPTION

The following describes modes (embodiments) for carrying out the present disclosure in detail with reference to the drawings. The present disclosure is not limited to the description of the embodiments given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### First Embodiment

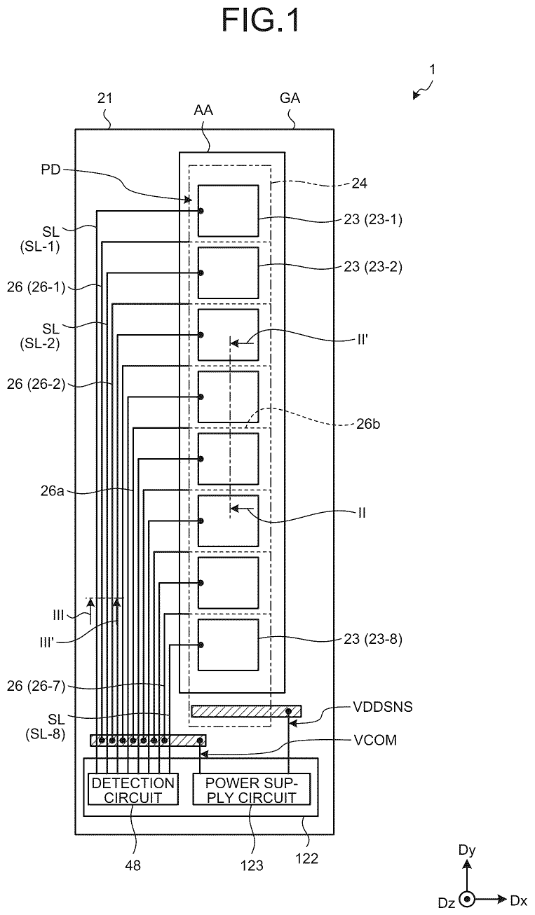

FIG. 1 is a plan view illustrating a detection device according to a first embodiment. As illustrated in FIG. 1, a detection device 1 includes a substrate 21, a plurality of photodiodes PD, a plurality of signal lines SL, a plurality of shield layers 26, and a control circuit 122.

The substrate 21 has a detection area AA and a peripheral area GA. The detection area AA is an area provided with the photodiodes PD. The peripheral area GA is an area between the outer perimeter of the detection area AA and the ends of the substrate 21 and is an area not provided with the photodiodes PD. The signal lines SL and the control circuit 122 are provided in the peripheral area GA of the substrate 21.

In the following description, a first direction Dx is one direction in a plane parallel to the substrate 21. A second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy. The third direction Dz is a direction normal to the substrate 21. The term “plan view” refers to a positional relation when viewed in a direction orthogonal to the substrate 21.

The detection device 1 includes the photodiodes PD as optical sensor elements. Each of the photodiodes PD outputs an electrical signal corresponding to light emitted thereto. More specifically, the photodiode PD is an organic photodiode (OPD) using an organic semiconductor. The photodiodes PD are arranged in the second direction Dy in the detection area AA.

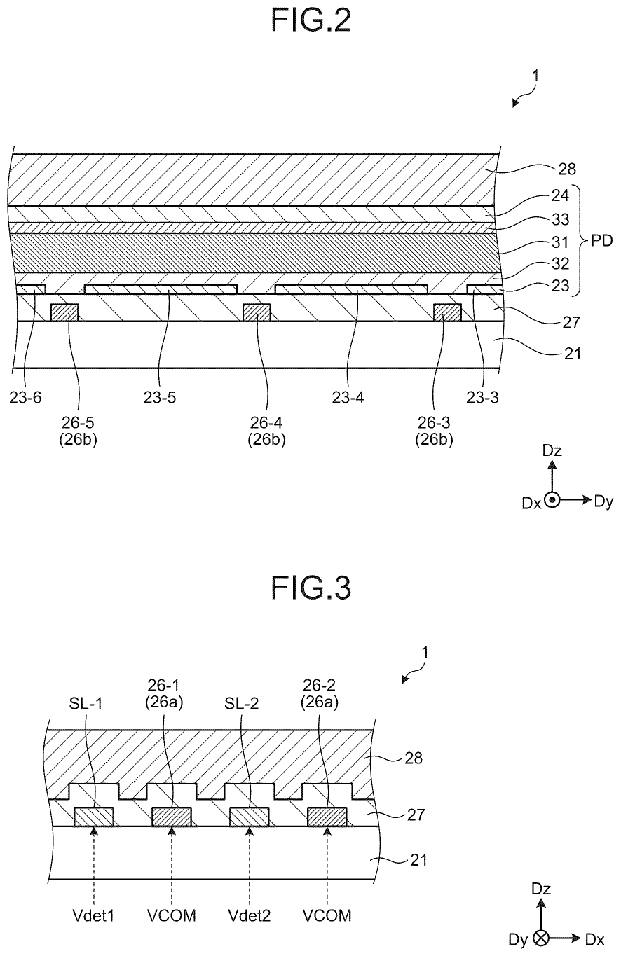

The photodiodes PD include a lower electrode 23 disposed on the lower side of the organic semiconductor and an upper electrode 24 disposed on the upper side of the organic semiconductor. A plurality of the lower electrodes 23 are provided, one for each of the photodiodes PD, and are arranged in the second direction Dy in the detection area AA. The lower electrodes 23 are arranged apart from one another in the second direction Dy. The upper electrode 24 is provided extending across the area of the photodiodes PD and provided continuously in the detection area AA. The configuration of the photodiodes PD, the lower electrodes 23, and the upper electrode 24 will be described later with reference to FIG. 2.

The signal lines SL are electrically coupled to the respective lower electrodes 23 of the photodiodes PD. Specifically, in the example illustrated in FIG. 1, lower electrodes 23-1, 23-2, . . . , 23-8 are arranged in the second direction Dy and provided for the photodiodes PD, respectively. Signal lines SL-1, SL-2, . . . , SL-8 are respectively coupled to the lower electrodes 23-1, 23-2, . . . , 23-8. In the following description, the signal lines SL-1, SL-2, . . . , SL-8 will each be simply referred to as a signal line SL when need not be distinguished from one another. The lower electrodes 23-1, 23-2, . . . , 23-8 will also each be simply referred to as the lower electrode 23 when need not be distinguished from one another.

Each of the signal lines SL extends in the first direction Dx from a coupling point with the lower electrode 23, bends to the second direction Dy, and extends in the second direction Dy along the arrangement direction of the photodiodes PD. The portions of the signal lines SL-1, SL-2, . . . , SL-8 extending in the second direction Dy are arranged in the first direction Dx. The signal lines SL are coupled to a detection circuit 48 included in the control circuit 122. In other words, the detection circuit 48 is electrically coupled to the lower electrodes 23 of the photodiodes PD through the signal lines SL.

The shield layers 26 are arranged between the signal lines SL in plan view. Specifically, each of shield layers 26-1, 26-2, . . . , 26-7 is disposed between a corresponding pair of the signal lines SL-1, SL-2, . . . , SL-8. In the following description, the shield layers 26-1, 26-2, . . . , 26-7 will each be simply referred to as a shield layer 26 when need not be distinguished from one another.

The shield layers 26 include first shield portions 26a that extend in the second direction Dy and second shield portions 26b that are coupled to the first shield portions 26a and extend in the first direction Dx. Each of the first shield portions 26a is disposed between portions of the signal lines SL extending in the second direction Dy and extends along the signal lines SL. Each of the second shield portions 26b is disposed between portions of the signal lines SL extending in the first direction Dx and extends between the lower electrodes 23 in plan view.

The first shield portions 26a of the shield layers 26 extend in the second direction Dy and are coupled to a power supply circuit 123 included in the control circuit 122. The power supply circuit 123 supplies a reference voltage VCOM to the shield layers 26. The reference voltage VCOM is a voltage signal having a fixed predetermined potential. The reference voltage VCOM is, for example, a voltage signal having an equal potential to a sensor reference voltage COM supplied to the lower electrodes 23. The power supply circuit 123 supplies a sensor power supply signal VDDSNS to the upper electrode 24 of the photodiodes PD.

In the peripheral area GA of the substrate 21, the control circuit 122 (detection circuit 48 and power supply circuit 123) is located adjacent to the photodiodes PD in the second direction Dy. The control circuit 122 is a circuit that controls detection operations by supplying control signals to the photodiodes PD. Each of the photodiodes PD outputs the electrical signal corresponding to the light emitted thereto as a detection signal Vdet to the detection circuit 48. In the present embodiment, the detection signals Vdet of the photodiodes PD are sequentially output to the detection circuit 48 in a time-division manner. In other words, the signal lines SL are sequentially electrically coupled to the detection circuit 48 in a time-division manner. Thereby, the detection device 1 detects information on an object to be detected based on the detection signals Vdet from the photodiodes PD.

The control circuit 122 (detection circuit 48 and power supply circuit 123) is provided on the same substrate 21 as the photodiodes PD, but is not limited to this configuration. The control circuit 122 (detection circuit 48 and power supply circuit 123) may be provided on another control substrate coupled to the substrate 21, for example, through a flexible printed circuit board or the like. The detection circuit 48 and the power supply circuit 123 may each be formed as an individual circuit.

Although not illustrated in FIG. 1, the detection device 1 may include one or more light sources. For example, an inorganic light-emitting diode (LED) or an organic electroluminescent (EL) diode (organic light-emitting diode (OLED)) is used as the light source.

Light emitted from the light source is reflected by the object to be detected such as a finger and enters the photodiodes PD. As a result, the detection device 1 can detect a fingerprint by detecting a shape of asperities on the surface of the finger or the like. Alternatively, the light emitted from the light source may be reflected in the finger or the like, or transmitted through the finger or the like, and enter the photodiodes PD. As a result, the detection device 1 can detect information on a living body in the finger or the like. Examples of the information on the living body include pulse waves, pulsation, and a vascular image of the finger or a palm. That is, the detection device 1 may be configured as a fingerprint detection device to detect a fingerprint or a vein detection device to detect a vascular pattern of, for example, veins.

The following describes a multilayer configuration of the photodiodes PD and the shield layers 26. FIG. 2 is a sectional view along II-II′ of FIG. 1.

In the following description, a direction from the substrate 21 toward a sealing film 28 in a direction orthogonal to a surface of the substrate 21 is referred to as “upper side” or simply “above”. A direction from the sealing film 28 toward the substrate 21 is referred to as “lower side” or simply “below”.

As illustrated in FIG. 2, the substrate 21 is an insulating substrate and is made using, for example, glass or a resin material. The substrate 21 is not limited to having a flat plate shape and may have a curved surface. In this case, the substrate 21 may be made of a film-like resin.

The shield layer 26 is provided on the substrate 21. The shield layer 26 is formed of, for example, metal wiring and is formed of a material having better conductivity than the lower electrode 23 of the photodiode PD. The shield layer 26 is provided between the substrate 21 and the photodiode PD in the third direction Dz. As described above, the second shield portion 26b of the shield layer 26 is located between the lower electrodes 23 of the adjacent photodiodes PD. An insulating film 27 is provided on the substrate 21 so as to cover the shield layer 26. The insulating film 27 may be an inorganic insulating film or an organic insulating film.

The photodiode PD is provided on the insulating film 27. In more detail, the photodiode PD includes the lower electrode 23, a lower buffer layer 32, an active layer 31, an upper buffer layer 33, and the upper electrode 24. In the photodiode PD, the lower electrode 23, the lower buffer layer 32 (hole transport layer), the active layer 31, the upper buffer layer 33 (electron transport layer), and the upper electrode 24 are stacked in this order in the direction orthogonal to the substrate 21.

The lower electrode 23 is an anode electrode of the photodiode PD and is formed of, for example, a light-transmitting conductive material such as indium tin oxide (ITO). The detection device 1 of the present embodiment is formed as a bottom-surface light receiving optical sensor in which the light from the object to be detected passes through the substrate 21 and enters the photodiode PD.

The active layer 31 changes in characteristics (for example, voltage-current characteristics and resistance value) depending on light emitted thereto. An organic material is used as a material of the active layer 31. Specifically, the active layer 31 has a bulk heterostructure containing a mixture of a p-type organic semiconductor and an n-type fullerene derivative ((6,6)-phenyl-C₆₁-butyric acid methyl ester (PCBM)) that is an n-type organic semiconductor. As the active layer 31, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using any of the low-molecular-weight organic materials listed above. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 31 can be a film made of a mixture of P3HT and PCBM, or a film made of a mixture of F8BT and PDI.

The lower buffer layer 32 is a hole transport layer and the upper buffer layer 33 is an electron transport layer. The lower buffer layer 32 and the upper buffer layer 33 are provided to facilitate holes and electrons generated in the active layer 31 to reach the lower electrode 23 or the upper electrode 24. The lower buffer layer 32 (hole transport layer) is in direct contact with the top of the lower electrode 23 and is also provided in areas between the adjacent lower electrodes 23. The active layer 31 is in direct contact with the top of the lower buffer layer 32. The material of the hole transport layer is a metal oxide layer. For example, tungsten oxide (WO₃) or molybdenum oxide is used as the metal oxide layer.

The upper buffer layer 33 (electron transport layer) is in direct contact with the top of the active layer 31, and the upper electrode 24 is in direct contact with the top of the upper buffer layer 33. Polyethylenimine ethoxylated (PEIE) is used as a material of the electron transport layer.

The materials and the manufacturing methods of the lower buffer layer 32, the active layer 31, and the upper buffer layer 33 are merely exemplary, and other materials and manufacturing methods may be used. For example, each of the lower buffer layer 32 and the upper buffer layer 33 is not limited to a single-layer film, and may be formed as a multilayered film that includes an electron block layer and a hole block layer.

The upper electrode 24 is provided on the upper buffer layer 33. The upper electrode 24 is a cathode electrode of the photodiode PD and is continuously formed over the entire detection area AA. In other words, the upper electrode 24 is continuously provided as the top layer of the photodiodes PD. The upper electrode 24 faces the lower electrodes 23 with the lower buffer layer 32, the active layer 31, and the upper buffer layer 33 interposed therebetween. The upper electrode 24 is formed of, for example, a light-transmitting conductive material such as ITO or indium zinc oxide (IZO).

The sealing film 28 is provided on the upper electrode 24. An inorganic film such as a silicon nitride film or an aluminum oxide film or a resin film such as an acrylic film is used as the sealing film 28. The sealing film 28 is not limited to a single layer, and may be a multilayered film having two or more layers obtained by combining the inorganic film with the resin film mentioned above. The sealing film 28 well seals the photodiode PD, and thus can reduce water entering the photodiode PD from the upper surface side thereof.

FIG. 3 is a sectional view along III-III′ of FIG. 1. As illustrated in FIG. 3, the signal lines SL are provided on the substrate 21. The shield layers 26 (first shield portions 26a) are provided in the same layer as the signal lines SL on the substrate 21 and are disposed between the adjacent signal lines SL. In the present embodiment, the signal lines SL and the shield layers 26 are alternately arranged in the first direction Dx in the following order: the signal line SL-1, the shield layer 26-1 (first shield portion 26a), the signal line SL-2, the shield layer 26-2 (first shield portion 26a), . . . . The signal lines SL and the shield layers 26 are not limited to the configuration of being provided directly on the substrate 21 and may be provided above the substrate 21 with one or more layers of insulating films interposed therebetween.

The insulating film 27 is provided on the substrate 21 so as to cover the signal lines SL and the shield layers 26. In the area illustrated in FIG. 3, the photodiode PD is not provided, and the sealing film 28 is provided on the insulating film 27. The sealing film 28 is continuously provided over the detection area AA and the peripheral area GA.

As described above, the shield layers 26 are disposed between the adjacent signal lines SL and supplied with the reference voltage VCOM. The shield layer 26 reduces parasitic capacitance between the adjacent signal lines SL and reduces unintended capacitive coupling between the signal lines SL. Therefore, even when a potential difference occurs between the adjacent signal lines SL, variations in potential of the signal lines SL are reduced.

For example, during a read period (first read period) of the photodiode PD, a detection signal Vdet1 detected by a photodiode PD-1 (refer to FIG. 1) is output to the detection circuit 48 through the signal line SL-1. During the next read period (second read period), a detection signal Vdet2 detected by a photodiode PD-2 (refer to FIG. 1) is output to the detection circuit 48 through the signal line SL-2. In the second read period, the read of the photodiode PD-1 has already been completed, and the potential of the signal line SL-1 drops to near the reference voltage VCOM.

Thus, when the detection signals Vdet of the photodiodes PD are sequentially read, a case occurs where the potential difference between the adjacent signal lines SL becomes large. As described above, in the present embodiment, a plurality of the shield layers 26 are provided, whereby the variations in the potential of the adjacent signal lines SL are reduced, and variations in the detection signals Vdet output from the signal lines SL to the detection circuit 48 are reduced.

As illustrated in FIG. 2, the shield layers 26 (second shield portions 26b) are disposed between the adjacent lower electrodes 23 and supplied with the reference voltage VCOM. As a result, the shield layer 26 reduces parasitic capacitance between the adjacent lower electrodes 23 and reduces unintended capacitive coupling between the lower electrodes 23. Therefore, even when a potential difference between the lower electrodes 23 occurs at the adjacent photodiodes PD, variations in potential between the adjacent photodiodes PD are reduced. Therefore, the variations in the detection signals Vdet output from the photodiodes PD to the detection circuit 48 through the signal lines SL are reduced. As described above, the detection device 1 of the present embodiment can improve the accuracy of detection.

The reference voltage VCOM supplied to the shield layers 26 is not limited to the voltage equal to the sensor reference voltage COM supplied to the lower electrode 23. The reference voltage VCOM only needs to be the predetermined fixed voltage signal and may be, for example, a voltage signal equal to the sensor power supply signal VDDSNS (sensor voltage) supplied to the upper electrode 24.

### First Modification

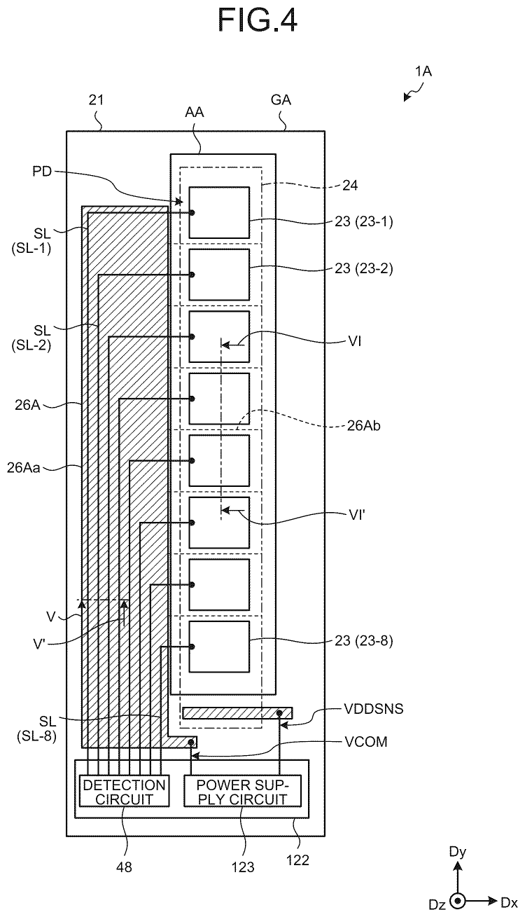

FIG. 4 is a plan view illustrating a detection device according to a first modification. In the following description, the same components as those described in the embodiment above are denoted by the same reference numerals, and the description thereof will not be repeated.

As illustrated in FIG. 4, in a detection device 1A according to the first modification, a shield layer 26A is continuously provided, overlapping the signal lines SL and extending across the area of the signal lines SL. In more detail, the shield layer 26A has a first shield portion 26Aa and a plurality of second shield portions 26Ab coupled to the first shield portion 26Aa. The first shield portion 26Aa is rectangular in plan view and is continuously provided so as to overlap the signal lines SL and extend across the area of the signal lines SL. In other words, at least portions of the shield layer 26A (first shield portion 26Aa) are disposed between the signal lines SL in plan view.

The width in the first direction Dx of the first shield portion 26Aa is larger than the overall width of the signal lines SL (that is, the width in the first direction Dx of the area from the signal line SL-1 to the signal line SL-8). The second shield portions 26Ab are coupled to the first shield portion 26Aa, extend in the first direction Dx from the first shield portion 26Aa in plan view, and are provided between the lower electrodes 23 adjacent in the second direction Dy.

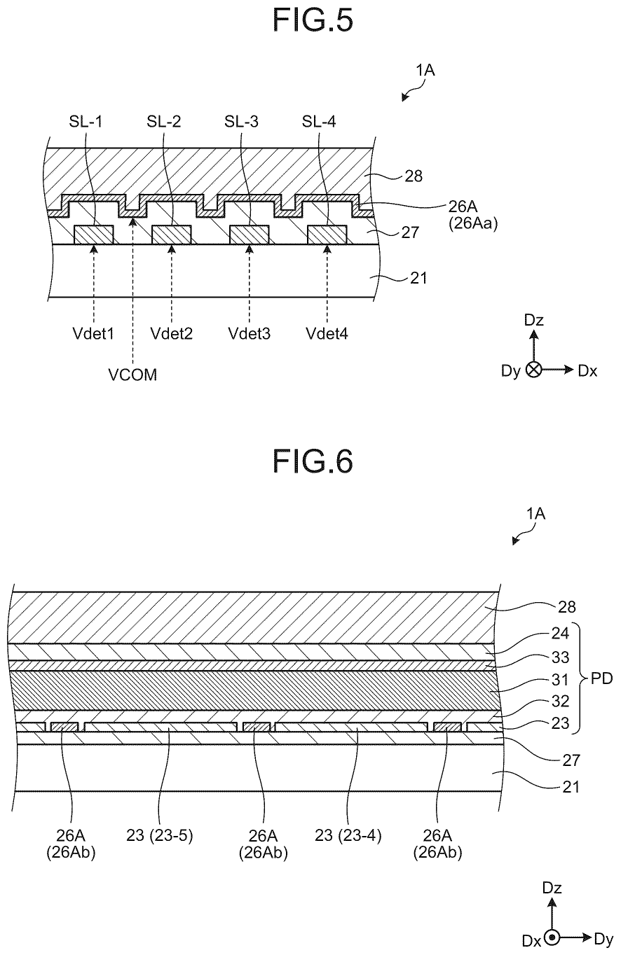

FIG. 5 is a sectional view along V-V′ of FIG. 4. As illustrated in FIG. 5, the insulating film 27 is provided on the substrate 21 so as to cover the signal lines SL. The first shield portion 26Aa of the shield layer 26A is provided on the insulating film 27. In other words, the shield layer 26A is provided in a layer above the signal lines SL, and is continuously provided over areas overlapping the signal lines SL and areas between the adjacent signal lines SL (areas not overlapping the signal lines SL). The sealing film 28 is provided above the insulating film 27 so as to cover the shield layer 26A.

FIG. 6 is a sectional view along VI-VI′ of FIG. 4. As illustrated in FIG. 6, the second shield portions 26Ab of the shield layer 26A are provided in the same layer as the lower electrodes 23 of the photodiodes PD on the insulating film 27. The second shield portions 26Ab of the shield layer 26A are each located between the lower electrodes 23 of the adjacent photodiodes PD. The lower buffer layer 32 is provided so as to cover the lower electrodes 23 and the second shield portions 26Ab.

In also the first modification, the first shield portion 26Aa of the shield layer 26A reduces the parasitic capacitance between the adjacent signal lines SL. In addition, the second shield portions 26Ab of the shield layer 26A reduce the parasitic capacitance between the adjacent lower electrodes 23. Furthermore, in the first modification, the shield layer 26A is provided so as to cover the signal lines SL, whereby noise entering the signal lines SL from outside (sealing film 28 side of the detection device 1A) can be well blocked. The first shield portion 26Aa of the shield layer 26A is provided in a different layer from the signal lines SL, whereby the arrangement pitch of the signal lines SL can be reduced, and the flexibility of layout of the signal lines SL can be improved as compared with the first embodiment described above. The second shield portions 26Ab of the shield layer 26A are provided in the same layer as the lower electrodes 23 of the photodiodes PD, whereby variations in potential between the adjacent lower electrodes 23 can be reduced as compared with the first embodiment.

### Second Modification

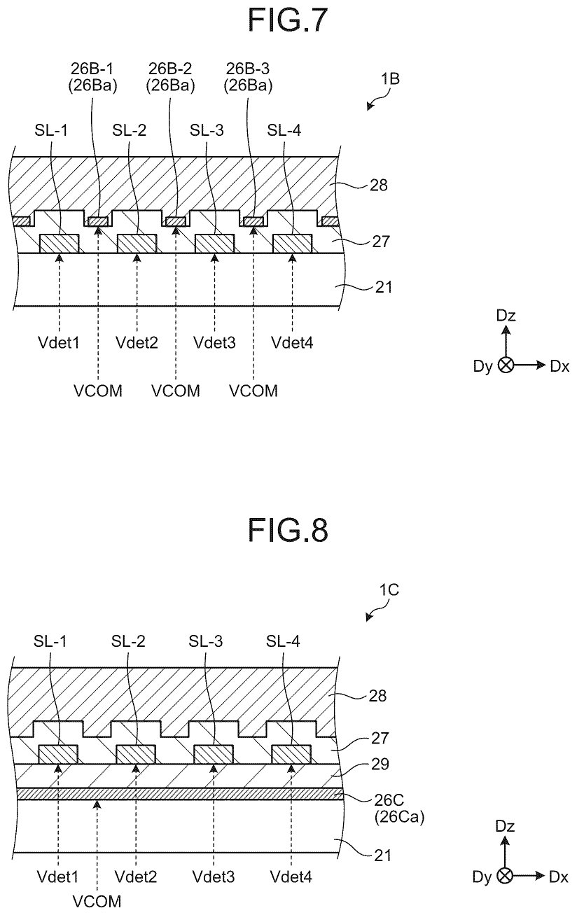

FIG. 7 is a sectional view schematically illustrating the signal lines and shield layers of a detection device according to a second modification. The plan view of a detection device 1B according to the second modification is similar to FIG. 1, and therefore, is not illustrated again.

As illustrated in FIG. 7, in the detection device 1B according to the second modification, shield layers 26B are provided on the insulating film 27 and are disposed between the adjacent signal lines SL in plan view. In other words, unlike in the first modification described above, first shield portions 26Ba of the shield layers 26B are not provided in areas overlapping the signal lines SL but are provided in areas between the adjacent signal lines SL (areas not overlapping the signal lines SL).

Each of the first shield portions 26Ba is formed in a line shape along the signal line SL in the same way as the first shield portion 26a illustrated in FIG. 1. In the example illustrated in FIG. 7, the signal lines SL and the shield layers 26B are alternately arranged in the first direction Dx in the following order: the signal line SL-1, a shield layer 26B-1, the signal line SL-2, a shield layer 26B-2, the signal line SL-3, a shield layer 26B-3, the signal line SL-4, . . . .

In the second modification, the area of the shield layers 26B provided above the signal lines SL is smaller than in the first modification described above, whereby the capacitance generated between the signal lines SL and the shield layers 26B is reduced. Therefore, even when the shield layers 26B are provided, the time constant of the signal lines SL is reduced, and the increase in time required to read the detection signals Vdet can be reduced.

### Third Modification

FIG. 8 is a sectional view schematically illustrating the signal lines and a shield layer of a detection device according to a third modification. The plan view of a detection device 1C according to the third modification is similar to FIG. 4, and therefore, is not illustrated again.

As illustrated in FIG. 8, in the detection device 1C according to the third modification, a shield layer 26C is provided in a layer between the substrate 21 and the signal lines SL in the third direction Dz. Specifically, the shield layer 26C is provided on the substrate 21. An insulating film 29 is provided so as to cover the shield layer 26C and the signal lines SL are provided on the insulating film 29. In the third modification, the shield layer 26C, the insulating film 29, the signal lines SL, the insulating film 27, and the sealing film 28 are stacked in this order on the substrate 21.

The shield layer 26C is formed in a rectangular shape in plan view in the same way as in FIG. 4 and is continuously provided, overlapping the signal lines SL and extending across the area of the signal lines SL. In other words, the shield layer 26C is provided in a layer below the signal lines SL and is continuously provided extending across the area including areas overlapping the signal lines SL and areas between the adjacent signal lines SL (areas not overlapping the signal lines SL).

In also the third modification, a first shield portion 26Ca of the shield layer 26C reduces the parasitic capacitance between the adjacent signal lines SL. Furthermore, in the third modification, the shield layer 26C is provided below the signal lines SL and is continuously provided extending across the area of the signal lines SL, whereby noise entering the signal lines SL from the substrate 21 side (lower side) can be well blocked. The shield layer 26C is provided in a different layer from the signal lines SL and the lower electrodes 23 of the photodiodes PD, whereby the flexibility of arrangement of the shield layer 26C can be improved as compared with the first embodiment and the modifications described above.

### Fourth Modification

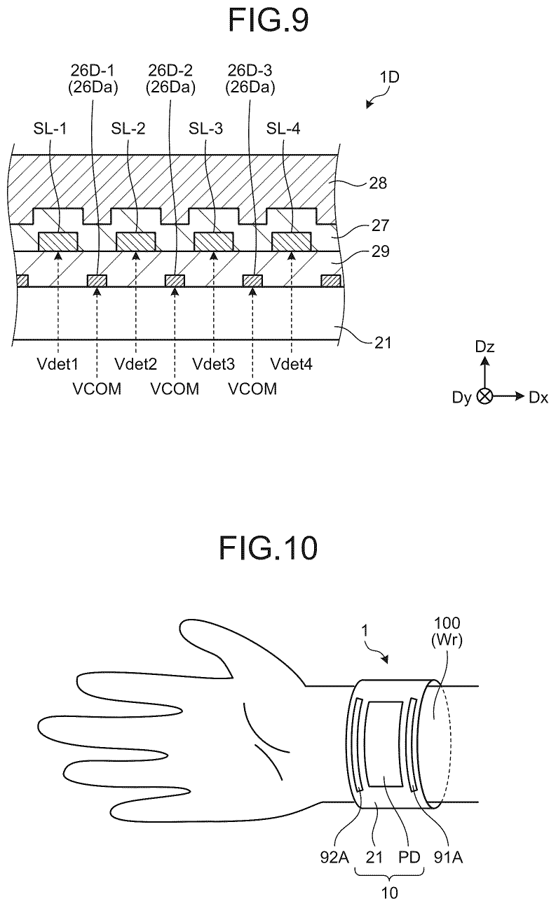

FIG. 9 is a sectional view schematically illustrating the signal lines and shield layers of a detection device according to a fourth modification. The plan view of a detection device 1D according to the fourth modification is similar to FIG. 1, and therefore, is not illustrated again.

As illustrated in FIG. 9, in the detection device 1D according to the fourth modification, shield layers 26D are provided in a layer between the substrate 21 and the signal lines SL and are disposed between the adjacent signal lines SL in plan view. In other words, unlike in the third modification described above, first shield portions 26Da of the shield layers 26D are provided in a layer below the signal lines SL, not in areas overlapping the signal lines SL, but in areas between the adjacent signal lines SL (areas not overlapping the signal lines SL). In the example illustrated in FIG. 9, the signal lines SL and the shield layers 26D are alternately arranged in the first direction Dx in the following order: the signal line SL-1, a shield layer 26D-1, the signal line SL-2, a shield layer 26D-2, the signal line SL-3, a shield layer 26D-3, the signal line SL-4, . . . .

In the fourth modification, the area of the shield layers 26D below the signal lines SL is smaller than in the third modification described above, whereby the capacitance generated between the signal lines SL and the shield layers 26D is reduced. Therefore, even when the shield layers 26D are provided, the time constant of the signal lines SL is reduced, and the increase in time required to read the detection signals Vdet can be reduced.

The first embodiment and the modifications described above can be combined as appropriate. That is, the detection device is not limited to being provided with one layer of the shield layers 26, 26A, 26B, 26C, and 26D, but may be provided with two or more layers. For example, the shield layer 26 of the first embodiment may be provided in combination with the shield layer 26A of the first modification. Alternatively, the shield layer 26 of the first embodiment may be provided in combination with the shield layer 26B of the second modification. The present disclosure is not limited to these combinations, and the shield layers 26, 26A, 26B, 26C, and 26D may be variously combined.

The first shield portion 26a provided between the signal lines SL and the second shield portion 26b provided between the lower electrodes 23 in plan view are coupled together to be formed as the continuous shield layer 26. However, the present disclosure is not limited to this configuration. The first shield portion 26a and the second shield portion 26b may be provided separately from each other and formed as individual shield layers.

FIG. 10 is a side view illustrating an exemplary use of the detection device according to the first embodiment for measuring biometric information. The first embodiment and the modifications described above illustrate the configuration in which the photodiodes PD are arranged in the second direction Dy. Such a detection device 1 can be used to observe a vein pattern of a wrist Wr serving as an object to be detected 100, as illustrated in FIG. 10.

The substrate 21 of the detection device 1 is formed of a deformable flexible material and is provided in a ring shape surrounding the wrist Wr. Light sources 91A and 92A are arranged in an arc shape along the substrate 21 provided in the ring shape. Light L emitted from the light sources 91A and 92A is reflected by blood vessels (veins) serving as the object to be detected 100 and enters the photodiodes PD of a sensor 10. The detection device 1 may be formed in a ring shape annularly provided around the finger, not limited to the wrist Wr. Alternatively, the detection device 1 can be employed in a smartwatch or a wearable device, for example. The arrangement of the light sources 91A and 92A illustrated in FIG. 10 is merely exemplary and can be changed as appropriate depending on an apparatus on which the detection device 1 is mounted.

### Second Embodiment

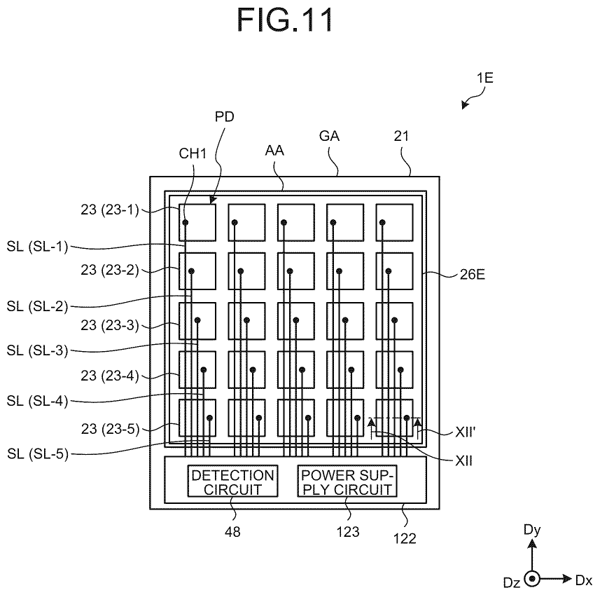

FIG. 11 is a plan view illustrating a detection device according to a second embodiment. As illustrated in FIG. 11, in a detection device 1E according to the second embodiment, the photodiodes PD are arranged in a matrix having a row-column configuration in the detection area AA of the substrate 21. The lower electrodes 23 are provided, one for each of the photodiodes PD, and arranged in a matrix having a row-column configuration in the detection area AA. In other words, the photodiodes PD (electrodes 23) are arranged in the first direction Dx and the second direction Dy. The upper electrode 24 (not illustrated in FIG. 11) is provided extending across the area of the photodiodes PD and continuously provided in the detection area AA.

The signal lines SL are electrically coupled to the respective lower electrodes 23 of the photodiodes PD, extend over an area overlapping the lower electrodes 23, and are electrically coupled to the detection circuit 48. For example, the signal lines SL-1, SL-2, . . . , SL-5 are respectively coupled to the lower electrodes 23-1, 23-2, . . . , 23-5 of the photodiodes PD arranged in the second direction Dy. The signal lines SL-1, SL-2, . . . , SL-5 are arranged in the first direction Dx in plan view.

The signal line SL-1 coupled to the lower electrode 23-1 extends in the second direction Dy so as to overlap the lower electrodes 23-2, 23-3, 23-4, and 23-5. The signal line SL-2 coupled to the lower electrode 23-2 extends in the second direction Dy so as to overlap the lower electrodes 23-3, 23-4, and 23-5. The signal line SL-3 coupled to the lower electrode 23-3 extends in the second direction Dy so as to overlap the lower electrodes 23-4 and 23-5. The signal line SL-4 coupled to the lower electrode 23-4 extends in the second direction Dy so as to overlap the lower electrode 23-5. A plurality of groups in each of which the photodiodes PD and the signal lines SL are arranged in the same arrangement relation in the second direction Dy are arranged in the first direction Dx.

A shield layer 26E is provided so as to cover most of the detection area AA and is continuously provided extending across the area of the signal lines SL and the photodiodes PD in plan view. That is, in the second embodiment, at least portions of the shield layer 26E are disposed between the signal lines SL in plan view.

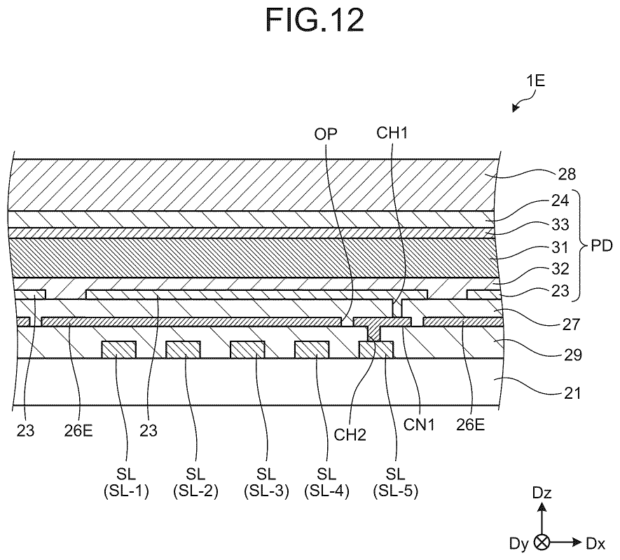

FIG. 12 is a sectional view along XII-XII′ of FIG. 11. As illustrated in FIG. 12, the signal lines SL, the insulating film 29, the shield layer 26E, the insulating film 27, and the photodiodes PD are stacked in this order in the third direction Dz on the substrate 21. The multilayer structure of the photodiode PD is the same as that in the first embodiment described above and will not be described in detail.

The shield layer 26E is formed in a layer between the signal lines SL and the lower electrodes 23 of the photodiodes PD. An opening OP is provided in an area overlapping the lower electrode 23 in the shield layer 26E. The lower electrode 23 of the photodiode PD is electrically coupled to the signal line SL through the opening OP provided in the shield layer 26E.

In more detail, a coupling electrode CN1 is provided in an area overlapping the opening OP in the same layer as the shield layer 26E. The coupling electrode CN1 is provided so as to be separated from the shield layer 26E with a slit interposed therebetween. The lower electrode 23 of the photodiode PD is electrically coupled to the coupling electrode CN1 through a contact hole CH1 provided in the insulating film 27. The coupling electrode CN1 is electrically coupled to the signal line SL-5 through a contact hole CH2 provided in the insulating film 29.

The shield layer 26E is provided in a layer above the signal lines SL and is continuously provided over the areas overlapping the signal lines SL and the areas between the adjacent signal lines SL (areas not overlapping the signal lines SL). Furthermore, the shield layer 26E is provided between the lower electrode 23 and the signal lines SL (signal lines SL-1 to SL-4 in FIG. 12) that are not coupled to this lower electrode 23.

With this configuration, the shield layer 26E reduces the parasitic capacitance between the adjacent signal lines SL. Therefore, the variations in potential of the signal lines SL are reduced even when the potential difference occurs between the adjacent signal lines SL. The shield layer 26E also reduces parasitic capacitance between the signal line SL and the lower electrode 23. Therefore, the variations in potential of the signal lines SL are reduced even when a potential difference occurs between the lower electrode 23 and the signal lines SL not coupled to the lower electrode 23.

### Third Embodiment

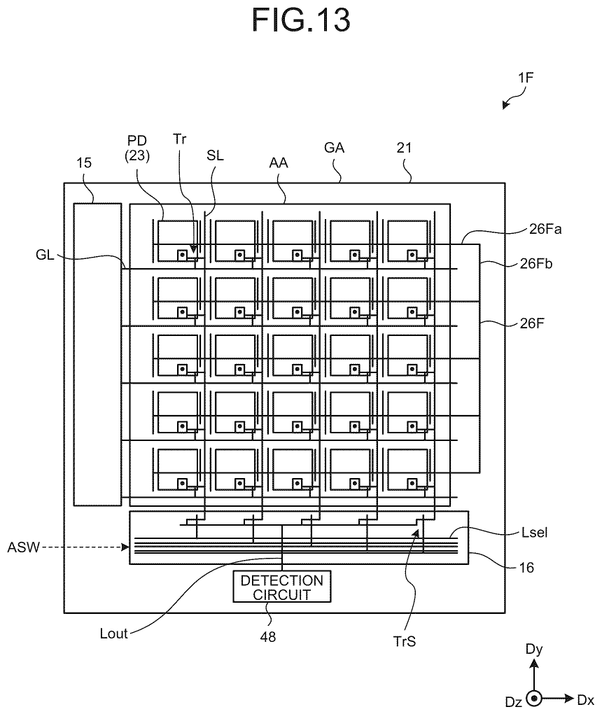

FIG. 13 is a plan view illustrating a detection device according to a third embodiment. As illustrated in FIG. 13, a detection device 1F according to the third embodiment further includes a plurality of drive transistors Tr, a plurality of gate lines GL, a gate line drive circuit 15, a signal line selection circuit 16, and a shield layer 26F.

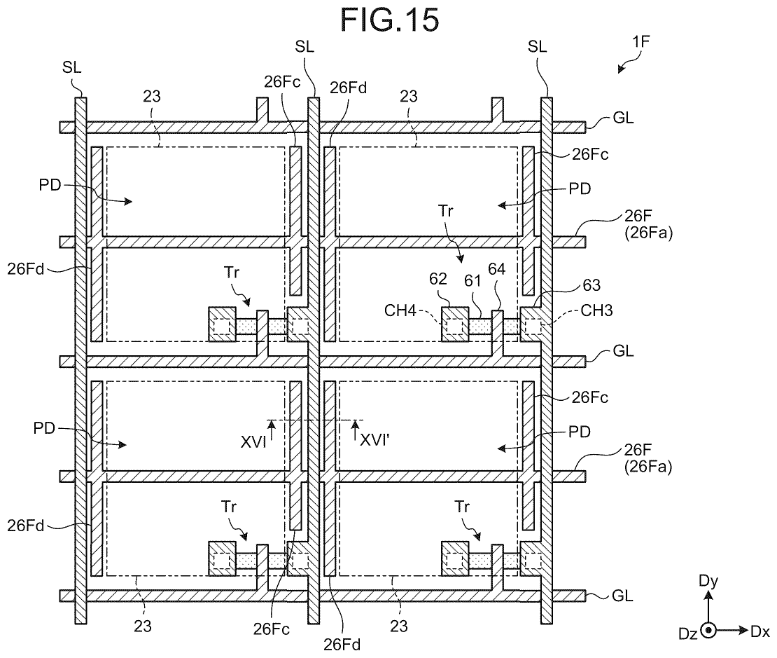

The photodiodes PD and the lower electrodes 23 are arranged in a matrix having a row-column configuration in the detection area AA. The drive transistors Tr are provided correspondingly to the photodiodes PD. The gate lines GL each extend in the first direction Dx and are arranged in the second direction Dy. The signal lines SL each extend in the second direction Dy and are arranged in the first direction Dx. The lower electrode 23 of the photodiode PD is located in an area surrounded by the gate lines GL and the signal lines SL. A detailed configuration of the shield layer 26F, the lower electrodes 23, and the signal lines SL will be described later with reference to FIG. 15.

The gate line drive circuit 15 and the signal line selection circuit 16 are provided in the peripheral area GA. Each of the photodiodes PD performs detection in response to a gate drive signal supplied from the gate line drive circuit 15. Each of the photodiodes PD outputs the electrical signal corresponding to the light emitted thereto as the detection signal Vdet to the signal line selection circuit 16. Thereby, the detection device 1 detects the information on the object to be detected based on the detection signals Vdet from the photodiodes PD.

In more detail, the gate line drive circuit 15 sequentially or simultaneously selects the gate lines GL and supplies the gate drive signals to the selected gate lines GL. As a result, the drive transistors Tr coupled to the gate lines GL are turned on (into a conduction state), and the lower electrodes 23 of the photodiodes PD coupled to the gate lines GL are electrically coupled to the signal lines SL via the drive transistors Tr.

The signal line selection circuit 16 is a switch circuit that sequentially or simultaneously selects the signal lines SL. The signal line selection circuit 16 is a multiplexer, for example. The signal line selection circuit 16 couples the selected signal lines SL to the detection circuit 48 based on a selection signal ASW supplied from the control circuit 122 (refer to FIG. 1). For example, the signal line selection circuit 16 includes a plurality of output transistors TrS, a plurality of selection signal lines Lsel coupled to the gates of the output transistors TrS, and an output signal line Lout.

Based on the selection signal ASW supplied through the selection signal lines Lsel, the output transistors TrS are sequentially turned on, and the selected signal lines SL are electrically coupled to the detection circuit 48 through the output signal line Lout. As a result, the signal line selection circuit 16 is electrically coupled to the photodiodes PD corresponding to the selected signal lines SL and outputs the detection signals Vdet of the photodiodes PD to the detection circuit 48.

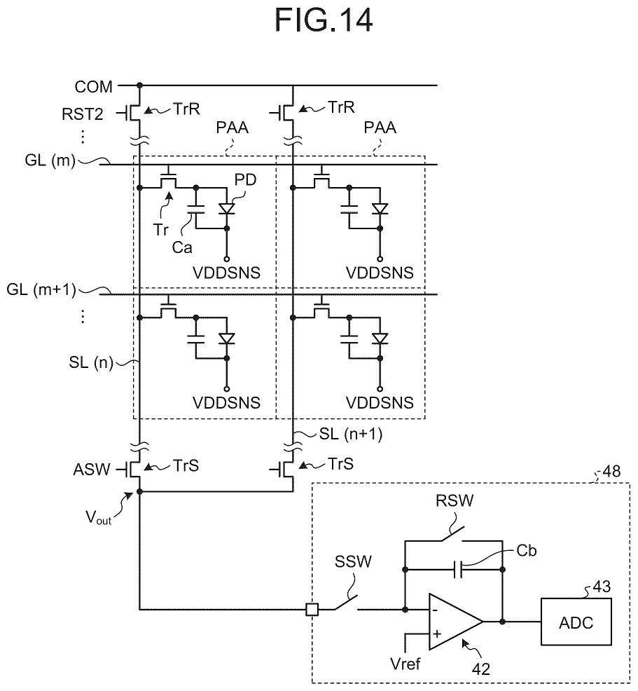

FIG. 14 is a circuit diagram illustrating the detection device according to the third embodiment. FIG. 14 also illustrates a circuit configuration of the detection circuit 48. As illustrated in FIG. 14, a partial detection area PAA includes the photodiode PD, a capacitive element Ca, and the drive transistor Tr. The capacitive element Ca is capacitance (sensor capacitance) generated in the photodiode PD and is equivalently coupled in parallel to the photodiode PD.

FIG. 14 illustrates two gate lines GL(m) and GL(m+1) arranged in the second direction Dy among the gate lines GL. FIG. 14 also illustrates two signal lines SL(n) and SL(n+1) arranged in the first direction Dx among the signal lines SL. The partial detection area PAA is an area surrounded by the gate lines GL and the signal lines SL.

The drive transistor Tr is provided correspondingly to each of the photodiodes PD. The drive transistor Tr is configured as a thin-film transistor, and in this example, configured as an n-channel metal oxide semiconductor (MOS) thin-film transistor (TFT).

The gates of the drive transistors Tr belonging to the partial detection areas PAA arranged in the first direction Dx are coupled to the gate line GL. One of the source and the drain of the drive transistor Tr belonging to each of the partial detection areas PAA arranged in the second direction Dy is coupled to the signal line SL. The other of the source and the drain of the drive transistor Tr is coupled to the anode of the photodiode PD and the capacitive element Ca.

The cathode of the photodiode PD is supplied with the sensor power supply signal VDDSNS from the power supply circuit 123 (refer to FIG. 1). The signal line SL and the capacitive element Ca are supplied with the sensor reference voltage COM serving as an initial potential of the signal line SL and the capacitive element Ca from the power supply circuit 123 via a reset transistor TrR.

When the partial detection area PAA is irradiated with light in an exposure period, a current corresponding to the amount of the light flows through the photodiode PD. As a result, an electric charge is stored in the capacitive element Ca. After the drive transistor Tr is turned on in a read period, a current corresponding to the electric charge stored in the capacitive element Ca flows through the signal line SL. The signal line SL is coupled to the detection circuit 48 through a corresponding one of the output transistors TrS of the signal line selection circuit 16. Thus, the detection device 1 can detect a signal corresponding to the amount of the light received by the photodiode PD in each of the partial detection areas PAA.

During a read period, a switch SSW is turned on to couple the detection circuit 48 to the signal lines SL. A detection signal amplifying circuit 42 of the detection circuit 48 converts a current supplied from the signal line SL into a voltage corresponding to the value of the current, and amplifies the result. A reference potential (Vref) having a fixed potential is supplied to a non-inverting input portion (+) of the detection signal amplifying circuit 42, and the signal line SL is coupled to an inverting input portion (−) of the detection signal amplifying circuit 42. In the present embodiment, the same signal as the sensor reference voltage COM is supplied as the reference potential (Vref) voltage. The control circuit 122 (refer to FIG. 1) calculates, as a sensor output voltage Vo, the difference between the detection signal Vdet when light is emitted and the detection signal Vdet when light is not emitted. The detection signal amplifying circuit 42 includes a capacitive element Cb and a reset switch RSW. During a reset period, the reset switch RSW is turned on to reset the electric charge of the capacitive element Cb.

FIG. 15 is a plan view illustrating, in an enlarged manner, the photodiodes and the shield layer in FIG. 13. As illustrated in FIG. 15, the shield layer 26F is disposed between the signal lines SL and the lower electrodes 23 in plan view. In more detail, the shield layer 26F includes a first shield portion 26Fa, a second shield portion 26Fb, a third shield portion 26Fc, and a fourth shield portion 26Fd. The first shield portion 26Fa extends in the first direction Dx. The second shield portion 26Fb couples together a plurality of the first shield portions 26Fa (refer to FIG. 13). The third and fourth shield portions 26Fc and 26Fd intersect the first shield portion 26Fa and extend in the second direction Dy. In the present embodiment, the portions included in the shield layer 26F are formed in the same layer as the gate line GL.

The first shield portion 26Fa is provided so as to overlap the photodiodes PD (lower electrodes 23) arranged in the first direction Dx and also intersects the signal lines SL. A plurality of the first shield portions 26Fa are provided, one for each of the photodiodes PD arranged in the second direction Dy.

The second shield portion 26Fb (refer to FIG. 13) extends in the second direction Dy in the peripheral area GA and couples the right ends of the first shield portions 26Fa to one another. As a result, the portions of the shield layer 26F are electrically coupled together and supplied with the common reference voltage VCOM.

The third shield portion 26Fc is coupled to the first shield portion 26Fa and is disposed between the right side of the lower electrode 23 and the signal line SL in plan view. The third shield portion 26Fc extends along the right side of the lower electrode 23 and the signal line SL.

The fourth shield portion 26Fd is coupled to the first shield portion 26Fa and is disposed between the left side of the lower electrode 23 and the signal line SL in plan view. The fourth shield portion 26Fd extends along the left side of the lower electrode 23 and the signal line SL. In other words, the lower electrode 23 is disposed between the third and the fourth shield portions 26Fc and 26Fd in the first direction Dx. Alternatively, the signal line SL is disposed between the third and the fourth shield portions 26Fc and 26Fd in the first direction Dx. The first shield portion 26Fa is arranged so as to overlap a central portion in the second direction Dy of the lower electrode 23. However, the first shield portion 26Fa is not limited to this arrangement and can be provided at any location in an area overlapping neither the gate line GL nor the drive transistor Tr.

The drive transistor Tr includes a semiconductor layer 61, a source electrode 62, a drain electrode 63, and a gate electrode 64. The semiconductor layer 61 extends along the gate line GL and is provided so as to intersect the gate electrode 64 in plan view. The gate electrode 64 is coupled to the gate line GL and extends in a direction orthogonal to the gate line GL. One end side of the semiconductor layer 61 is coupled to the source electrode 62 through a contact hole CH4. The lower electrode 23 is electrically coupled to the source electrode 62 of the drive transistor Tr through a contact hole (not illustrated). As a result, the drive transistor Tr is electrically coupled to the photodiode PD. The other end side of the semiconductor layer 61 is coupled to the drain electrode 63 through a contact hole CH3. The drain electrode 63 is coupled to the signal line SL.

The shield layer 26F is provided at a location not overlapping the drive transistor Tr. The first shield portion 26Fa is provided at a location overlapping neither the semiconductor layer 61 nor the gate electrode 64. The third shield portion 26Fc is located so as to be separate from the drain electrode 63 in the second direction Dy. The fourth shield portion 26Fd is provided between the gate lines GL adjacent in the second direction Dy and is located so as to be separate from each of the gate lines GL.

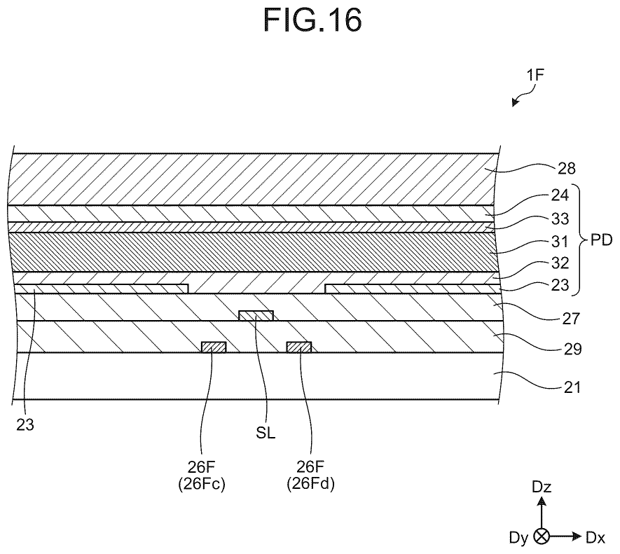

FIG. 16 is a sectional view along XVI-XVI′ of FIG. 15. As illustrated in FIG. 16, the shield layer 26F is provided in a layer between the substrate 21 and the lower electrode 23 of the photodiode PD in the third direction Dz. The shield layer 26F is provided in a layer between the substrate 21 and the signal line SL in the third direction Dz.

Specifically, the shield layer 26F is provided on the substrate 21. The insulating film 29 is provided on the substrate 21 so as to cover the shield layer 26F. The signal line SL is provided on the insulating film 29. The insulating film 27 is provided on the insulating film 29 so as to cover signal line SL. The lower electrode 23 of the photodiode PD is provided on the insulating film 27. The multilayer structure of the photodiode PD is the same as that of the first embodiment described above and will not be described again.

With such a configuration, the third and the fourth shield portions 26Fc and 26Fd of the shield layer 26F reduce the parasitic capacitance between the signal line SL and the lower electrode 23. Therefore, in the configuration in which the signal line SL is provided between the lower electrodes 23 of the photodiodes PD and the photodiodes PD are arranged along one signal line SL, the variations in potential of the signal lines SL are reduced even when a potential difference occurs between the signal line SL and the lower electrode 23.

### Fifth Modification

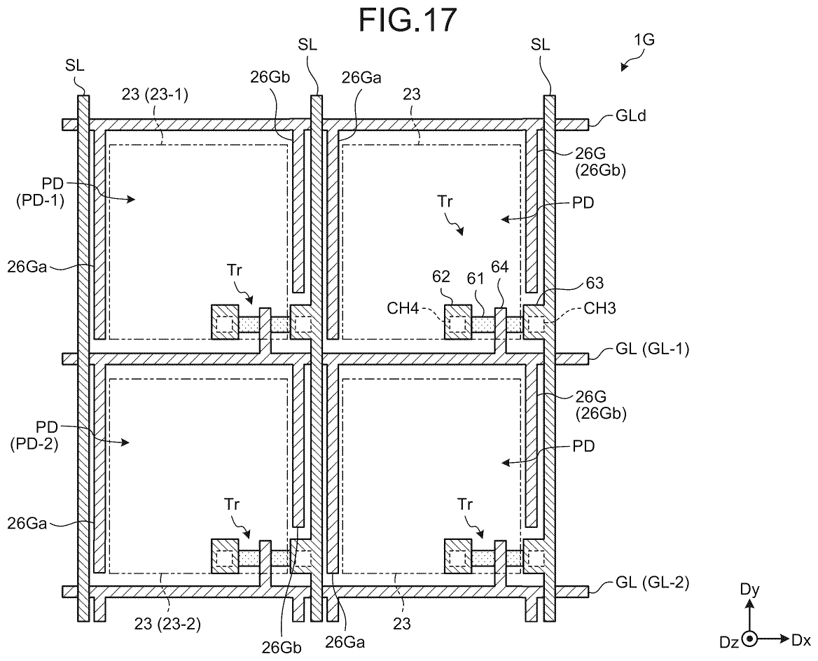

FIG. 17 is a plan view illustrating, in an enlarged manner, the photodiodes and shield layers of a detection device according to a fifth modification. The sectional view of a detection device 1G according to the fifth modification is similar to FIG. 16, and therefore, is not illustrated again.

As illustrated in FIG. 17, in the detection device 1G according to the fifth modification, a shield layer 26G is provided in the same layer as the gate line GL and coupled to the gate line GL. In more detail, FIG. 17 illustrates, in an enlarged manner, a plurality of photodiodes PD-1 belonging to the first row and a plurality of photodiodes PD-2 belonging to the second row. The photodiodes PD-1 are the photodiodes PD located on the most second direction Dy side of the detection area AA and away from the detection circuit 48 and the signal line selection circuit 16 (FIG. 13).

A gate line GL-1 is provided between the photodiodes PD-1 belonging to the first row and the photodiodes PD-2 belonging to the second row, and extends in the first direction Dx. The gate line GL-1 is coupled to the drive transistors Tr of the photodiodes PD-1. A gate line GL-2 is provided between the photodiodes PD-2 belonging to the second row and photodiodes PD-3 belonging to the third row (not illustrated in FIG. 17) and extends in the first direction Dx. The gate line GL-2 is coupled to the drive transistors Tr of the photodiodes PD-2.

In addition, a dummy wiring line GLd is provided on a side of photodiodes PD-1 opposite the gate line GL-1 (on the upper side of the photodiodes PD-1 in FIG. 17). The dummy wiring line GLd is not coupled to the drive transistor Tr and does not serve as the gate electrode 64. The photodiodes PD-1 belonging to the first row are arranged between the dummy wiring line GLd and the gate line GL-1 in the second direction Dy in plan view. The dummy wiring line GLd is provided so as to extend in the first direction Dx in the same layer as the gate line GL.

In the photodiodes PD-2 belonging to the second row, a first shield portion 26Ga of the shield layer 26G is coupled to the gate line GL-1, extends in the second direction Dy, and is disposed between the left side of the lower electrode 23-2 and the signal line SL in plan view. A second shield portion 26Gb of the shield layer 26G is coupled to the gate line GL-1, extends in the second direction Dy, and is disposed between the right side of the lower electrode 23-2 and the signal line SL in plan view. Thereafter, in the same way, the shield layer 26G coupled to a gate line GL-(m−1) corresponding to the (m−1)th row is disposed between the signal line SL and the lower electrodes 23 of photodiodes PD-m belonging to the mth row.

In the photodiodes PD-1 belonging to the first row, the first shield portion 26Ga of the shield layer 26G is coupled to the dummy wiring line GLd, extends in the second direction Dy, and is disposed between the left side of the lower electrode 23-1 and the signal line SL in plan view. The second shield portion 26Gb of the shield layer 26G is coupled to the dummy wiring line GLd, extends in the second direction Dy, and is disposed between the right side of the lower electrode 23-1 and the signal line SL in plan view.

As described above, the shield layer 26G provided for the photodiodes PD-m in the mth row is coupled to the gate line GL-(m−1) adjacent to a gate line GL-m in the mth row. The gate drive signal is supplied to the gate line GL-m selected by the gate line drive circuit 15, and the reference voltage VCOM is supplied to the unselected gate lines GL (for example, gate line GL-(m−1)). As a result, the reference voltage VCOM is supplied to the shield layer 26G provided for the photodiodes PD-m in the mth row through the unselected gate line GL-(m−1).

In the photodiodes PD-1 belonging to the first row, the shield layer 26G is coupled to the dummy wiring line GLd different from the gate line GL-1 coupled to the drive transistors Tr of the photodiodes PD-1. The dummy wiring line GLd is supplied with the reference voltage VCOM. As a result, the reference voltage VCOM is supplied to the shield layer 26G provided for the photodiodes PD-1 in the first row through the dummy wiring line GLd. The voltage supplied to the dummy wiring line GLd is not limited to the reference voltage VCOM and may be other reference voltages such as a high (H) level voltage or a low (L) level voltage of the gate drive signal.

With such a configuration, in also the fifth modification, the shield layer 26G reduces the parasitic capacitance between the signal line SL and the lower electrode 23. In addition, in the detection device 1G according to the fifth modification, the unselected gate line GL and the dummy wiring line GLd serve also as power supply wiring to the shield layer 26G. Therefore, in the fifth modification, the number of wiring lines can be reduced and the aperture ratio for the photodiode PD can be improved as compared with the third embodiment described above. Furthermore, the unselected gate line GL serves also as the shield layer 26G between the photodiode PDs adjacent in the second direction Dy. The dummy wiring line GLd serves also as the shield layer 26G on the peripheral area GA side of photodiode PD-1.

### Sixth Modification

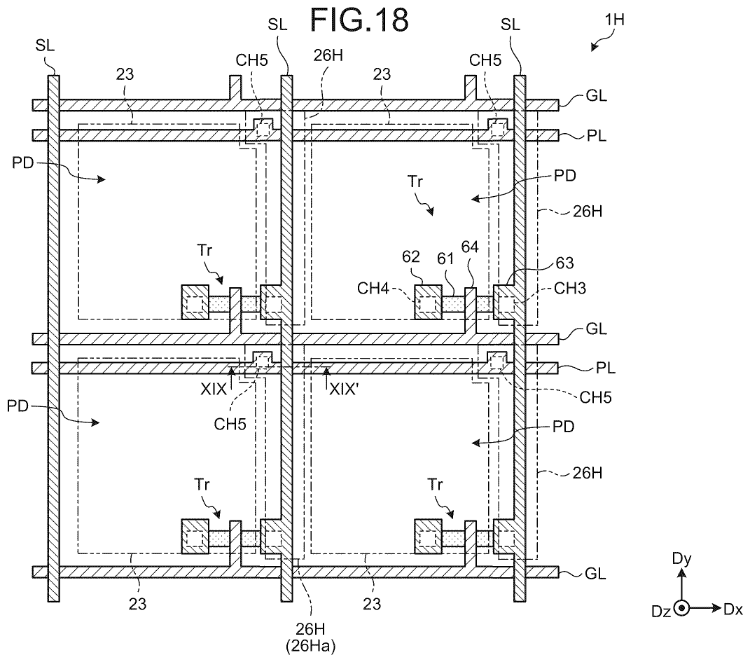

FIG. 18 is a plan view illustrating, in an enlarged manner, the photodiodes and shield layers of a detection device according to a sixth modification. As illustrated in FIG. 18, a detection device 1H according to the sixth modification includes a power supply wiring line PL extending in the first direction Dx, and a shield layer 26H extending in the second direction Dy so as to overlap the signal line SL.

The power supply wiring line PL is provided along the gate line GL in the same layer as the gate line GL and supplies the reference voltage VCOM to the shield layer 26H. The power supply wiring line PL is provided for each of the gate lines GL arranged in the second direction Dy. That is, the power supply wiring line PL is provided for each of the photodiodes PD arranged in the second direction Dy.

The shield layer 26H is electrically coupled to the power supply wiring line PL through a contact hole CH5. A plurality of the shield layers 26H are coupled to one power supply wiring line PL extending in the first direction Dx and are provided one for each of the photodiodes PD (lower electrodes 23). The shield layer 26H has a larger width than that of the signal line SL and is provided between the lower electrodes 23 of the adjacent photodiodes PD. In other words, the shield layer 26H includes, in plan view, a portion that overlaps the signal line SL and a portion that is disposed between the signal line SL and the lower electrode 23 without overlapping the signal line SL.

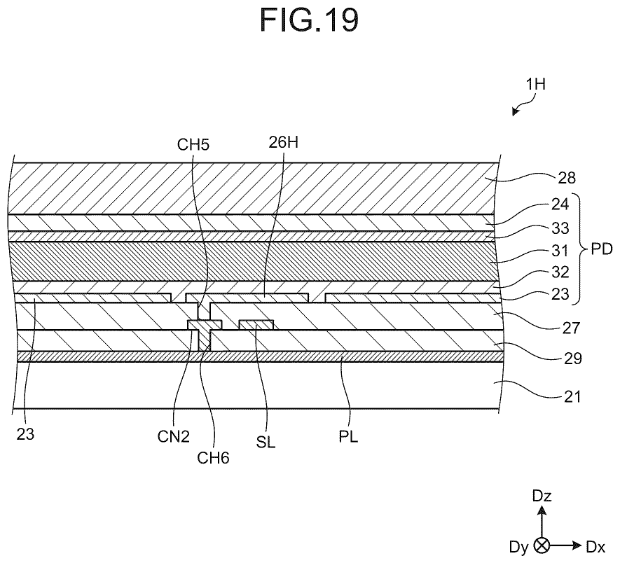

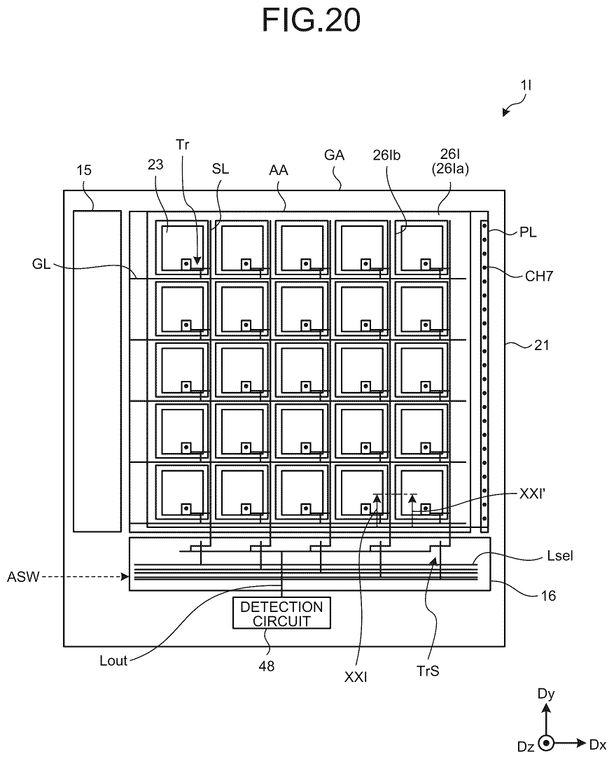

FIG. 19 is a sectional view along XIX-XIX′ of FIG. 18. As illustrated in FIG. 19, the power supply wiring line PL is provided between the substrate 21 and the shield layer 26H and between the substrate 21 and the lower electrode 23, in the third direction Dz. The shield layer 26H is provided in the same layer as the lower electrode 23 and is disposed between the lower electrodes 23 adjacent in the first direction Dx. The shield layer 26H is formed of the same material as the lower electrode 23, using a light-transmitting conductive material such as ITO. The power supply wiring line PL is formed of the same metal material as the gate line GL.

Specifically, the power supply wiring line PL is provided on the substrate 21. The insulating film 29 is provided above the substrate 21 so as to cover the power supply wiring line PL. The signal line SL is provided on the insulating film 29. A coupling electrode CN2 is provided in the same layer as the signal line SL on the insulating film 29 and is arranged adjacent to the signal line SL in an area overlapping the shield layer 26H. The insulating film 27 is provided on the insulating film 29 so as to cover the signal line SL and the coupling electrode CN2. The lower electrode 23 of the photodiode PD and the shield layer 26H are provided on the insulating film 27.

The shield layer 26H is electrically coupled to the coupling electrode CN2 through the contact hole CH5 provided in the insulating film 27. The coupling electrode CN2 is electrically coupled to the power supply wiring line PL through a contact hole CH6 provided in the insulating film 29. Thus, the power supply wiring line PL is electrically coupled to the shield layer 26H through the contact holes CH5 and CH6 provided in the insulating films 27 and 29 covering the power supply wiring line PL. The multilayer structure of the photodiode PD is the same as that of the first embodiment described above and will not be described again.

With such a configuration, in also the sixth modification, the shield layer 26H reduces the parasitic capacitance between the signal line SL and the lower electrode 23. Since the shield layer 26H is provided in the same layer as the lower electrode 23, the parasitic capacitance between the lower electrodes 23 adjacent in the first direction Dx is also reduced.

### Seventh Modification

FIG. 20 is a plan view illustrating a detection device according to a seventh modification. As illustrated in FIG. 20, in a detection device 1I according to the seventh modification, a shield layer 26I is provided in a grid pattern overlapping the signal lines SL and the gate lines GL. In more detail, the shield layer 26I includes a plurality of first shield portions 26Ia extending in the first direction Dx and a plurality of second shield portions 26Ib intersecting the first shield portions 26Ia and extending in the second direction Dy. The first shield portions 26Ia are arranged in the second direction Dy, each overlapping the gate line GL. The second shield portions 26Ib are arranged in the first direction Dx, each overlapping the signal line SL. The lower electrodes 23 are arranged in areas each surrounded by the first shield portions 26Ia and the second shield portions 26Ib in plan view.

The power supply wiring line PL is provided in the peripheral region GA and extends in the second direction Dy. The shield layer 26I is provided from the detection area AA to the peripheral area GA and is electrically coupled to the power supply wiring line PL through a plurality of contact holes CH7 in the peripheral area GA. The contact holes CH7 are arranged in the second direction Dy, and thereby, coupling between the power supply wiring line PL and the shield layer 26I can be ensured.

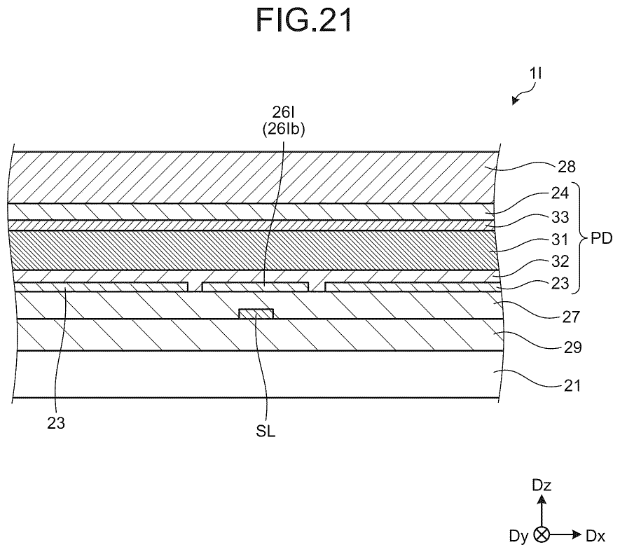

FIG. 21 is a sectional view along XXI-XXI′ of FIG. 20. As illustrated in FIG. 21, the shield layer 26I is provided in the same layer as the lower electrode 23 on the insulating film 27. Each of the second shield portions 26Ib of the shield layer 26I is disposed between the lower electrodes 23 adjacent in the first direction Dx. The second shield portion 26Ib has a larger width than that of the signal line SL and overlaps the signal line SL. That is, the second shield portion 26Ib includes, in plan view, a portion that overlaps the signal line SL and a portion that is disposed between the signal line SL and the lower electrode 23 without overlapping the signal line SL.

Although not illustrated, each of the first shield portions 26Ia of the shield layer 26I also has the same multilayer structure as the second shield portion 26Ib. The first shield portion 26Ia of the shield layer 26I is disposed between the lower electrodes 23 adjacent in the second direction Dy. The first shield portion 26Ia has a larger width than that of the gate line GL and overlaps the gate line GL. That is, the first shield portion 26Ia includes, in plan view, a portion that overlaps the gate line GL and a portion that is disposed between the gate line GL and the lower electrode 23 without overlapping the gate line GL.

Since the shield layer 26I is provided so as to cover most of the area of the detection area AA that does not overlap the lower electrodes 23, the parasitic capacitance between the signal line SL and the lower electrode 23 can be well reduced in the seventh modification.

The third embodiment and the fifth to the seventh modifications described above can be combined as appropriate. That is, the detection device is not limited to being provided with one layer of the shield layers 26F, 26G, 26H, and 26I, but may be provided with two or more layers. For example, the shield layer 26F of the third embodiment may be combined with the shield layer 26H of the sixth modification. The present disclosure is not limited to these combinations, and the shield layers 26F, 26G, 26H, and 26I may be variously combined.

In the first to the third embodiments and the modifications thereof described above, the lower electrode 23 is the anode electrode of the photodiode PD, and the upper electrode 24 is the cathode electrode of the photodiode PD. However, the present disclosure is not limited to this configuration. The lower electrode 23 may be the cathode electrode of the photodiode PD, and the upper electrode 24 may be the anode electrode of the photodiode PD. In that case, in the photodiode PD, the lower buffer layer 32 is configured with an electron transport layer, and the upper buffer layer 33 is configured with a hole transport layer.

The lower electrodes 23 all have a quadrilateral outer shape, but the outer shape is not limited thereto. The lower electrode 23 can have other shapes, such as a polygonal shape and a circular shape.

While the preferred embodiments of the present disclosure have been described above, the present disclosure is not limited to these embodiments. The content disclosed in the embodiments is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiments and the modifications described above.

What is claimed is:

1. A detection device comprising:
a substrate;
a plurality of photodiodes that are arranged on the substrate and each comprise a lower electrode, a lower buffer layer, an active layer, an upper buffer layer, and an upper electrode that are stacked on the substrate in the order as listed;
a plurality of signal lines electrically coupled to the respective lower electrodes of the photodiodes;
a detection circuit electrically coupled to the photodiodes through the signal lines; and
a shield layer disposed between the signal lines in plan view.

2. The detection device according to claim 1, wherein
the lower buffer layer comprises one of a hole transport layer and an electron transport layer, and
the upper buffer layer comprises the other of the hole transport layer and the electron transport layer.

3. The detection device according to claim 1, wherein
the shield layer comprises:
a first shield portion that is disposed between the signal lines and extends along the signal lines; and
a second shield portion that extends between a plurality of the lower electrodes.

4. The detection device according to claim 1, wherein a reference voltage supplied to the shield layer is equal to a sensor voltage supplied to the upper electrode.

5. The detection device according to claim 1, wherein a reference voltage supplied to the shield layer is equal to a sensor reference voltage supplied to the lower electrode.

6. The detection device according to claim 1, wherein the shield layer is provided in the same layer as the signal lines.

7. The detection device according to claim 1, comprising an insulating film provided on the substrate so as to cover the signal lines, wherein
the shield layer is provided on the insulating film.

8. The detection device according to claim 7, wherein the shield layer is continuously provided overlapping the signal lines and extending across an area of the signal lines.

9. The detection device according to claim 1, wherein the shield layer is provided between the substrate and the signal lines in a direction orthogonal to the substrate.

10. The detection device according to claim 9, wherein the shield layer is continuously provided overlapping the signal lines and extending across an area of the signal lines.

11. The detection device according to claim 1, wherein
the signal lines, the shield layer, and the photodiodes are stacked in the order as listed, in a direction orthogonal to the substrate,
the shield layer is continuously provided extending across an area of the signal lines and the photodiodes, and
the lower electrode of the photodiode is electrically coupled to a corresponding one of the signal lines through an opening provided in the shield layer.

12. A detection device comprising:
a substrate;
a plurality of photodiodes that are arranged on the substrate and each comprise a lower electrode, a lower buffer layer, an active layer, an upper buffer layer, and an upper electrode that are stacked on the substrate in the order as listed;
a plurality of signal lines electrically coupled to the respective lower electrodes of the photodiodes;
a detection circuit electrically coupled to the photodiodes through the signal lines; and
a shield layer disposed between a plurality of the lower electrodes in plan view.

13. The detection device according to claim 12, wherein the shield layer is provided in the same layer as the lower electrodes.

14. The detection device according to claim 12, wherein the shield layer is provided between the substrate and the lower electrodes in a direction orthogonal to the substrate.

15. A detection device comprising:
a substrate;
a plurality of photodiodes that are arranged on the substrate and each comprise a lower electrode, a lower buffer layer, an active layer, an upper buffer layer, and an upper electrode that are stacked on the substrate in the order as listed;
a plurality of signal lines electrically coupled to the lower electrodes of the photodiodes;
a detection circuit electrically coupled to the photodiodes through the signal lines; and
a shield layer disposed between the signal lines and the lower electrodes in plan view.

16. The detection device according to claim 15, comprising a power supply wiring line configured to supply a reference voltage to the shield layer, wherein
the shield layer is provided in the same layer as the lower electrode, and
the power supply wiring line is provided between the substrate and the shield layer and between the substrate and the lower electrode, in a direction orthogonal to the substrate, and is electrically coupled to the shield layer through a contact hole provided in an insulating film that covers the power supply wiring line.

17. The detection device according to claim 15, wherein the shield layer is provided in a layer between the substrate and the lower electrode in a direction orthogonal to the substrate.

18. The detection device according to claim 15, comprising a plurality of gate lines that extend in a direction intersecting the signal lines, wherein
the shield layer is provided in the same layer as the gate lines and is coupled to the gate lines.

19. The detection device according to claim 15, comprising a plurality of gate lines that extend in a direction intersecting the signal lines, wherein
the shield layer is provided in the same layer as the lower electrode, and
the shield layer is provided in a grid pattern overlapping the signal lines and the gate lines.
